(19) United States
(12) Patent Application Publication
(10) Pub. No.: US 2024/0234653 A9
(43) Pub. Date: Jul. 11, 2024

(54) COMPOSITE ENCAPSULATION MATERIAL AND OPTICAL DEVICE OF THE SAME

(71) Applicant: Lextar Electronics Corporation, Hsinchu City (TW)

(72) Inventors: Deng Kong SOH, Hsinchu City (TW); Wen Wan TAI, Hsinchu City (TW); Yu-Chun LEE, Hsinchu City (TW)

(21) Appl. No.: 18/492,977

(22) Filed: Oct. 24, 2023

(30) Foreign Application Priority Data
Oct. 24, 2022 (TW) 111140186

(51) Int. Cl. H01L 33/56; C08K 3/22; C08K 3/36; C09K 11/02; H01L 33/58

(52) U.S. Cl. CPC H01L 33/56; C08K 3/22; C08K 3/36; C09K 11/025; H01L 33/58; C08K 2003/2227; C08K 2003/2241; C08K 2201/005; C08K 2201/011

(57) ABSTRACT

A composite encapsulation material is provided, which includes (A) a polymer glue material and (B) a viscosity modifier. The viscosity modifier (B) has a functional group capable of forming non-covalent interaction with the polymer glue material (A). At room temperature, the ratio (log(η₀)/log(η₂₈ )) of the logarithm of the viscosity ((log(η₀)) of the composite encapsulation material at the shear rate of 1×10⁻³ s⁻¹ to the logarithm of the viscosity (log(η_{∞})) of the composite encapsulation material at the shear rate of 1×10² s⁻¹ is 1.1-2.5.

### CROSS REFERENCE TO RELATED APPLICATIONS

This Application claims priority of Taiwan Patent Application No. 111140186, filed on Oct. 24, 2022, and the entirety of which is incorporated by reference herein.

### TECHNICAL FIELD

The present application relates to a composite encapsulation material for light-emitting diodes (LED) and optical devices that include the composite encapsulation material in particular.

### DESCRIPTION OF BACKGROUND ART

Light-emitting diode (LED) light sources have advantages of high efficiency, long product lifecycle, and no harmful substances such as mercury (Hg). With the continuous improvement of technology in the field of light-emitting diodes, the brightness and lifetime of light-emitting diodes have been greatly improved, making the application of light-emitting diodes more and more extensive. The old light sources used in applications from outdoor lighting such as street lights to indoor lighting such as decorative lights are generally being replaced by light-emitting diodes.

Light-emitting diodes need to be packaged in a suitable form for an end product to be put into practical use. Generally, the function of packaging is to provide sufficient protection for the chip to prevent the chip from being exposed to the air for a long time, or from mechanical damage so as to improve the stability of the chip. It is also necessary for light-emitting diode packaging to have good light extraction efficiency (LEE) and good heat dissipation. Good packaging can make light-emitting diodes have better luminous efficiency and heat dissipation, thereby improving the lifetime of light-emitting diodes.

In addition, packaging is also a key process in the manufacturing of white light-emitting diodes. The light-emitting mechanism of semiconductor materials determines that a single light-emitting diode chip cannot emit white light with a continuous spectrum, so in the manufacturing process, two or more complementary colors of light must be mixed to form white light. At present, there are three main methods to realize white light-emitting diodes: (1) blue light-emitting diodes with yellow (YAG) phosphor powder, (2) RGB three-color light-emitting diodes, (3) ultraviolet light-emitting diodes with multi-color phosphor powders. The realization of white light-emitting diodes by packaging, good process precision control, and good materials and equipment are the guarantee for the stability of white light-emitting diode devices.

At present, conventional light-emitting diode packaging technology uses a phosphor encapsulation process, that is, the phosphor powder and the glue are mixed with a certain proportion, and then the phosphor powder glue is coated on the surface of light-emitting diode by an automatic dispenser machine. By using this method, the optical performance of the light-emitting chip is improved. However, the density of the phosphor powder is higher than that of the glue, and there is a certain density difference between the two. When the two substances are mixed together, the phosphor powder can be sedimented and dispersed in the phosphor powder glue unevenly, which makes the light to be mixed unevenly, so the white light emitted by the component is not uniform, and there can be blue and yellow ring phenomenon appearing around the light spot, which greatly affects product performance.

In addition, the conventional encapsulation material have better adhesion due to the better wetting effect of the glue material and the substrate. Therefore, it is difficult for the glue material to maintain the shape after dispensing, which means the glue material can be spread and cannot form an ideal lens itself, and therefore affects the light extraction efficiency.

### BRIEF SUMMARY OF THE APPLICATION

An embodiment of the present application provides a composite encapsulation material, which comprises: (A) a polymer glue material; and (B) a viscosity modifier. The viscosity modifier (B) has a functional group that is capable of forming a non-covalent interaction with the polymer glue material (A). At room temperature, the ratio (log(η₀)/log(η_{∞})) of the a logarithm of the a viscosity (log(η₀)) of the composite encapsulation material at a shear rate of 1×10⁻³ s⁻¹ to the a logarithm of the a viscosity (log(η_{∞})) of the composite encapsulation material at a shear rate of 1×10² s⁻¹ is 1.1-2.5.

An embodiment of the present application provides an optical device, which comprises the composite encapsulation material in the present disclosure.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1A shows a diagram of the relationship between the logarithm of viscosity (log(η)) and the logarithm of the shear rate (log(γ)) of conventional encapsulation material, according to some embodiments.

FIG. 1B shows a diagram of the relationship between the logarithm of viscosity (log(η)) and the logarithm of the shear rate (log(γ)) of composite encapsulation material in the present disclosure, according to some embodiments.

FIG. 2A shows a schematic diagram of the structure of the composite encapsulation material in the present disclosure under unstressed state.

FIG. 2B shows a schematic diagram of the structure of the composite encapsulation material in the present disclosure when under stress.

FIG. 3 shows a schematic diagram of an optical device including the composite encapsulation material in the present disclosure, according to some embodiments.

FIG. 4 shows a schematic diagram of an optical device including the composite encapsulation material in the present disclosure, according to some other embodiments.

FIG. 5 shows a diagram of the relationship between the logarithm of viscosity (log(η)) and the logarithm of the shear rate (log(γ)) of different examples.

### DETAILED DESCRIPTION OF THE APPLICATION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described below. In the different drawings and described embodiments, like reference numerals are used to designate like elements. It is understood that additional steps may be provided before, during, and after the method, and that some recited steps may be substituted or deleted in other embodiments of the method.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about”, “approximate”, and the like, the term is intended to encompass numbers that are within a reasonable range considering variations that inherently arise during manufacturing as understood by one of ordinary skill in the art.

In the present embodiment, the viscosity is defined as the viscosity value measured under the environment of temperature 25° C.±5° C., humidity 50±10% RH and standard pressure (100 kPa). Even if the viscosity values are measured outside the range above, as long as they are adjusted to the temperature 25° C.±5° C., humidity 50±10% RH, and standard pressure falls within the range specified in the present disclosure, then they are also included in the scope of the present embodiment. In addition, the terms “standard temperature” and “room temperature” herein refer to a temperature of about 20° C. to 30° C.

In the present embodiment, “γ” refers to the shear rate with the unit of s⁻¹, and “η” refers to the viscosity with the unit of mPa·s. “η0” refers to the viscosity of the encapsulation material when the shear rate is 1×10⁻³ s⁻¹ at room temperature (25° C.±5° C.); “η_{∞}” refers to the viscosity of the encapsulation material at room temperature when the shear rate is 1×10² s⁻¹. In addition, “log(η₀)” refers to the base 10 logarithm of η₀; “log(η_{∞})” refers to the base 10 logarithm of η₂₈; “log(γ)” refers to the base 10 logarithm of γ.

A composite encapsulation material are provided, which includes (A) a polymer glue material and (B) a viscosity modifier. The viscosity modifier (B) has a functional group capable of forming non-covalent forces with the polymer glue material (A). At room temperature, the ratio (log(η₀)/log(η_{∞})) of the logarithm of the viscosity (η₀) of the composite encapsulation material at a shear rate of 1×10⁻³ s⁻¹ to the logarithm of the viscosity (η_{∞}) of the composite encapsulation material at a shear rate of 1×10² s⁻¹ is 1.1-2.5.

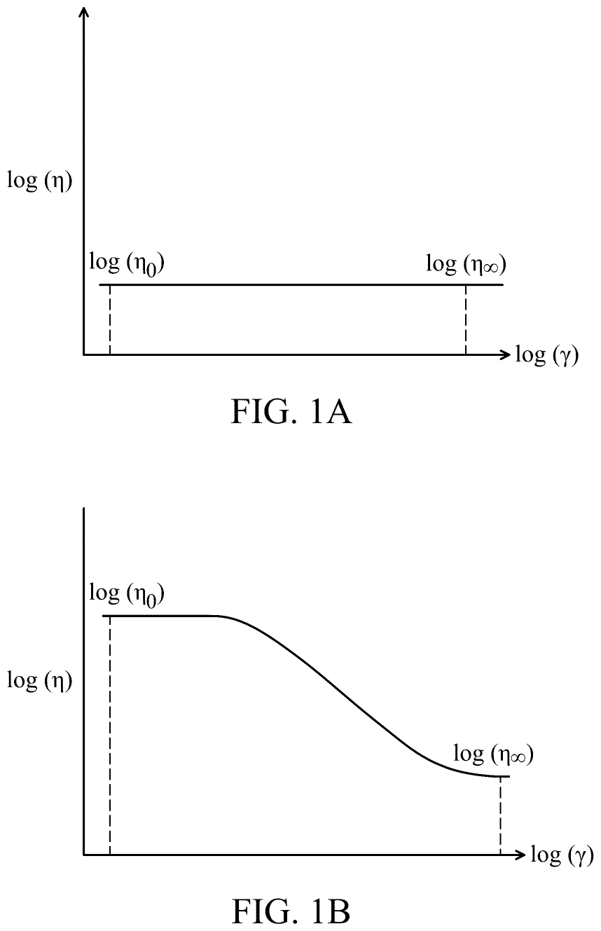

Referring to FIG. 1A and FIG. 1B, the viscosity of the disclosed composite encapsulation material will be described further. In FIGS. 1A-1B, “η₀” refers to the viscosity of the encapsulation material at room temperature and the shear rate (γ) of 1×10⁻³ s⁻¹; “η_{∞}” refers to the viscosity of the encapsulation material at room temperature and the shear rate (γ) of 1×10² s⁻¹.

FIG. 1A is a diagram of the relationship between the logarithm of viscosity (log(η)) and the logarithm of the shear rate (log(γ)) of conventional encapsulation material at room temperature (25° C.±5° C.). As shown in FIG. 1A, the ratio of the logarithm of η₀ to the logarithm of η_{∞} of the encapsulation material currently available in the market is substantially equal to 1 (that is, log(η₀)/log(η_{∞})=1). Regardless of the environment and process operating conditions, the viscosity of conventional encapsulation material is a fixed value. In terms of the processability, the viscosity cannot be too high, or the phosphor powder in the encapsulation material may sediment and the encapsulation material have difficulty maintaining its shape after dispensing, which causes glue material to spread. FIG. 1B is a diagram of the relationship between the logarithm of viscosity (log(η)) and the logarithm of the shear rate (log(γ)) of composite encapsulation material in the present embodiment at room temperature (25° C.±5° C.). As shown in FIG. 1B, the viscosity of the disclosed composite encapsulation material decreases with the increasing shear rate. By adding a specific modifier in the encapsulation material, the functional group(s) of the modifier can form non-covalent interaction, such as van der Waals forces, hydrogen bonds, ionic bonds, hydrophobic interactions, or a combination thereof, with the polymer glue material in the encapsulation material. Therefore, the formed composite encapsulation material has a tangled net structure and the log(η₀)/log(η_{∞}) of the material≠1.

Since the viscosity of the composite encapsulation material in the present embodiment is close to a constant value at a shear rate under 1×10⁻³ s⁻¹, when the shear rate is below 1×10⁻³ s⁻¹, the composite encapsulation material can be regarded as under static state (unstressed state). Therefore, the η₀ is set as the viscosity at a shear rate of 1×10⁻³ s⁻¹. As the shear rate increases (the shear rate is greater than 1×10⁻³ s⁻¹), the external force on the composite encapsulation material increases, and the molecules of the composite encapsulation material are disturbed (considered as being in a stressed state), so that the non-covalent interaction between the molecules is weakened, resulting in a gradual decrease in viscosity. When the added amount of modifiers reaches a certain level, the slurry separation due to high rotation speed in the measurement may occur, resulting in poor stability of the measured value and losing the value of material judgment. Therefore, the η_{∞} is set as the viscosity at a shear rate of 1×10⁻² s⁻¹1.

In some embodiments, the polymer glue material (A) includes siloxane bonds, carbon-hydrogen bonds, or a combination thereof. In some embodiments, the polymer glue material (A) includes silicone resin, epoxy resin, fluororesin, or a combination thereof.

The silicone resin may be, for example, a resin containing siloxane bonds and having an organic functional group such as an alkyl group or an aromatic group as a constituent unit. The aforementioned alkyl group is not limited particularly to such as a methyl group, an ethyl group, a propyl group, an isopropyl group, a butyl group, an isobutyl group, a sec-butyl group, a tert-butyl group. The aforementioned aromatic group is not limited particularly to such as a phenyl group, a benzyl group, or the like. Specifically, the silicone resin may be, for example, dimethylpolysiloxane, methylphenylpolysiloxane, diphenylpolysiloxane. In addition, the silicone resin may also include epoxy modified silicone resin, alkyd modified silicone resin, acrylic modified silicone resin, polyester modified silicone resin, etc., or a combination thereof.

Above-mentioned epoxy resin, can be a bisphenol-A based epoxy resin, a bisphenol-F based epoxy resin, a phenol novolac epoxy, a tetrabromobisphenol epoxy resin, and a rubber modified epoxy resin, an alicyclic epoxy resin, an aliphatic epoxy resin, or a combination thereof.

Above-mentioned fluororesin can be polyvinyl fluoride (PVF), polyvinylidene difluoride (PVDF), polytrifluoroethylene (PTrFE), polychlorotrifluoroethylene (PCTFE), polytetrafluoroethylene (PTFE); copolymer can be ethylene-tetrafluoroethylene copolymer (ETFE), ethylene-chlorotrifluoroethylene copolymer, tetrafluoroethylene-hexafluoropropylene copolymer, tetrafluoroethylene-perfluoropropyl vinyl ether copolymer, or a combination thereof.

In addition, the polymer glue material (A) may also include other resins, such as acrylic resins, vinyl ester resin, urea resins, polyimide resin, polyphenylene sulfide, or a combination thereof. Examples of acrylic resins include poly(methyl methacrylate) (PMMA) and poly(ethylene glycol dimethacrylate) (PEGMA). Examples of vinyl resins include poly(vinyl acetate) (PVA) and poly(divinylbenzene) (PDVB).

In some embodiments, other additives maybe included in the polymer glue material (A), such as curing agent, curing accelerator, silane coupling agent, flame retardant, flame retardant auxiliary agent, release agent, ion capture agents, pigments/colorants, stress reducers, adhesives, or a combination thereof.

In some embodiments, the functional groups of the viscosity modifier (B) that are capable of forming a non-covalent force with the polymer glue material (A) include —OH, ═NH, —NH₂, halogen, hydrocarbon chain, or a combination thereof. In some embodiments, the viscosity modifier (B) includes a polymer material, a nanomaterial, or a combination thereof.

In some embodiments, the polymer material in the viscosity modifier (B) includes polyamide wax, organic bentonite clay, hydrogenated castor oil, or a combination thereof. The organic bentonite may be bentonite having cetyltrimethylammonium ions, bentonite having tetramethylammonium ions, or the like. According to some embodiments, based on 100 parts by weight of the polymer glue material (A), the polymer material used as the viscosity modifier (B) may be 1-100 parts by weight, such as 5-95 parts by weight, 10-90 parts by weight, 15-85 parts by weight, 20-80 parts by weight, 25-75 parts by weight, 30-70 parts by weight, 35-60 parts by weight, 40-55 parts by weight, or 45-50 parts by weight.

In some embodiments, the particle size of the nanomaterial in the viscosity modifier (B) may be 1 nm-500 nm, such as 3 nm-480 nm, 5 nm-450 nm, 8 nm-420 nm, 10 nm-400 nm, 15 nm-380 nm, 20 nm-350 nm, 25 nm-320 nm, 30 nm-300 nm, 35 nm-250 nm, 40 nm-200 nm, 50 nm-150 nm, 55 nm-100 nm, 60 nm-95 nm, 70 nm-90 nm, or 75 nm-85 nm. According to some embodiments, based on 100 parts by weight of the polymer glue material (A), the nanomaterial used as the viscosity modifier (B) may be 0.1-130 parts by weight, such as 0.5-125 parts by weight, 1.5-121 parts by weight, 5-115 parts by weight, 10-110 parts by weight, 15-105 parts by weight, 20-100 parts by weight, 25-95 parts by weight, 30-90 parts by weight, 35-85 parts by weight, 40-80 parts by weight, 45-75 parts by weight, 50-70 parts by weight, or 55-60 parts by weight.

In some embodiments, the nanomaterials include luminescent materials, non-luminescent materials, or a combination thereof. In some embodiments, the non-luminescent material includes TiO₂, SiO₂, Al₂O₃, or a combination thereof. In some embodiments, the luminescent material includes quantum dots.

Different functional groups may be introduced to the non-luminescent material through surface modification. For example, it can be conducted by hydrophobic surface modification, hydrophilic surface modification, and the like. For example, the surface of the non-luminescent material may be coated with trimethylchlorosilane, triethylchlorosilane, triphenylchlorosilane, dimethylchlorosilane, dimethyldichlorosilane, polydimethylsiloxane, hydroxyl polydimethylsiloxane, poly (methyl methacrylate), fatty acid, silicon oxide, aluminum oxide, etc. According to some embodiments, the non-luminescent material is capable of forming non-covalent interaction such as hydrogen bonds, van der Waals forces, ionic bonds, and hydrophobic interactions with the polymer material (A) in the present embodiment.

The quantum dots may comprise II-VI semiconductor compounds, III-V semiconductor compounds, IV-VI semiconductor compounds, or a combination thereof. The structure of quantum dots may include the core region that mainly emits light and the shell that covers the core region. The material of the core region may comprise zinc sulfide (ZnS), zinc selenide (ZnSe), zinc telluride (ZnTe), zinc oxide (ZnO), cadmium sulfide (CdS), cadmium selenide (CdSe), cadmium telluride (CdTe), gallium nitride (GaN), gallium phosphide (GaP), gallium selenide (GaSe), gallium antimonide (GaSb), gallium arsenide (GaAs), aluminum nitride (AlN), aluminum phosphide (AlP), aluminum arsenide (AlAs), indium phosphide (InP), indium arsenide (InAs), tellurium (Te), lead sulfide (PbS), indium antimonide (InSb), lead telluride (PbTe), lead selenide (PbSe), antimony telluride (SbTe), zinc cadmium selenide (ZnCdSe), zinc cadmium selenium sulfide (ZnCdSeS), copper indium sulfide (CuInS), or a combination thereof. The material of the shell and the material of the core region match each other (e.g., the lattice constants of the materials of the core region and the shell need to match).

Specifically, with respect to the material composition of the shell, in addition to taking the lattice constant match for the material of the core region into consideration, another consideration is forming a high energy barrier region around the core region to increase the quantum yield. In order to satisfy these two properties at the same time, the structure and/or composition of the shell can be modified to reduce the stress of the core region and the shell on the one hand and increase the energy barrier on the other hand. The structure of the shell may be a single-layer structure, a multi-layer structure or a material composition gradient structure.

In one embodiment, the core region is cadmium selenide, and the shell is a single layer of zinc sulfide. In another embodiment, the core region is cadmium selenide, and the shell includes the inner layer of (cadmium, zinc) (sulfur, selenium) and the outer layer of zinc sulfide.

In another embodiment, the core is cadmium selenide, the shell includes the inner layer of cadmium sulfide, the middle graded layer of Zn_{0.25}Cd_{0.75}S/Zn_{0.5}Cd_{0.5}S/Zn_{0.75}Cd_{0.25}S, and the outer layer of zinc sulfide. In some embodiments, the quantum dots can form non-covalent interactions such as ionic bonds, van der Waals forces, hydrogen bonds, and hydrophilic-hydrophobic interactions with the polymer glue material (A).

In some embodiments, the composite encapsulation material further include phosphor, and the type of phosphor is not restricted particularly. For example, it may be yellow, red, green, or blue light-emitting phosphor powders widely used in light-emitting diodes, such as oxide-based phosphor powder, nitrogen oxide-based phosphor powder, nitride-based phosphor powder, sulfide-based phosphor powder, and oxysulfide-based phosphor powder. Phosphor powder materials may be, for example, Y₃Al₅O₁₂:Ce, Gd₃Ga₅O₁₂:Ce, Lu₃Al₅O₁₂:Ce, (Lu, Y)₃Al₅O₁₂:Ce, Tb₃Al₅O₁₂:Ce, SrS:Eu, SrGa₂S₄:Eu, (Sr, Ca, Ba)(Al, Ga)₂S₄:Eu, (Ca, Sr)S:(Eu, Mn), (Ca, Sr)S:Ce, (Ba, Sr, Ca)₂SiO₄:Eu, (Ca, Sr, Ba)Si₂O₂N₂:Eu, (Sr, Ba, Ca)₂Si₅N₈:Eu, (Sr, Ba, Ca)(Al, Ga)SiN₃:Eu, SrLiAl₃N₄:Eu, Ba₂LiSi₇AlN₁₂:Eu, K₂SiF₆:Mn, K₂TiF₆:Mn, K₂SnF₆:Mn, or a combination thereof.

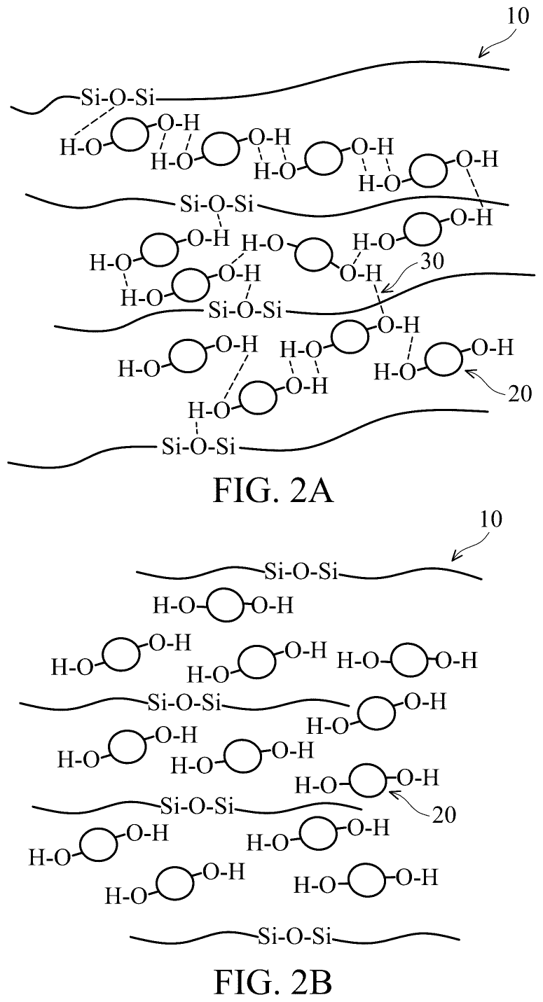

Referring to FIGS. 2A-2B, the structures of the composite encapsulation material in the embodiments of the present disclosure in different states is described below. FIG. 2A is a schematic diagram of the structure of the composite encapsulation material under static state and FIG. 2B is a schematic diagram of the structure of the composite encapsulation material when being stressed. In the present embodiment, a viscosity modifier (B) is added in encapsulation material and the surface of the viscosity modifier (B) has functional groups that is capable of forming a non-covalent interaction with the polymer glue material (A) in the composite encapsulation material so that the molecular structure of the composite packaging entangles to form a net structure. As shown in FIG. 2A, in some embodiments, the polymer glue material 10 in the composite encapsulation material in the present embodiment contains siloxane bonds (—Si—O—Si—), and the viscosity modifier 20 contains hydroxyl groups (—OH). Therefore, a non-covalent interaction 30, such as hydrogen bond, is formed and makes the molecules in the encapsulation material entangle with each other, thereby increasing the viscosity between the encapsulation material. However, as the shear rate on the composite encapsulation material in the present embodiment increases, the encapsulation material is disturbed, the non-covalent interaction 30 between the polymer glue material 10 and the viscosity modifier 20 weakens, and the structure of the composite encapsulation material becomes looser with a lower viscosity of the encapsulation material, as shown in FIG. 2B. In addition, once the force applied to the encapsulation material in the present embodiment is weakened or ceased, the viscosity of the encapsulation material is increased or recovered quickly. In contrast, due to the lack of non-covalent interaction, conventional encapsulation material have a loose molecular structure that does not change whether it is under stress or not. Therefore, its viscosity is substantially constant at different shear rates.

The encapsulation material disclosed in this embodiment can be applied to different light-emitting diode package types, such as surface mount device (surface mount device, SMD) and chip direct bonding (chip on board, COB), to form an optical device including the composite encapsulation material in the present embodiment. In some embodiments, the optical device includes a light-emitting unit, and the composite encapsulation material in the present embodiment covers the light-emitting unit in the optical device. In some embodiments, the light-emitting unit may be a light-emitting diode chip. In some embodiments, the optical device further comprises an optical unit, wherein the optical unit is made of the composite encapsulation material. In some embodiments, the optical unit is a lens.

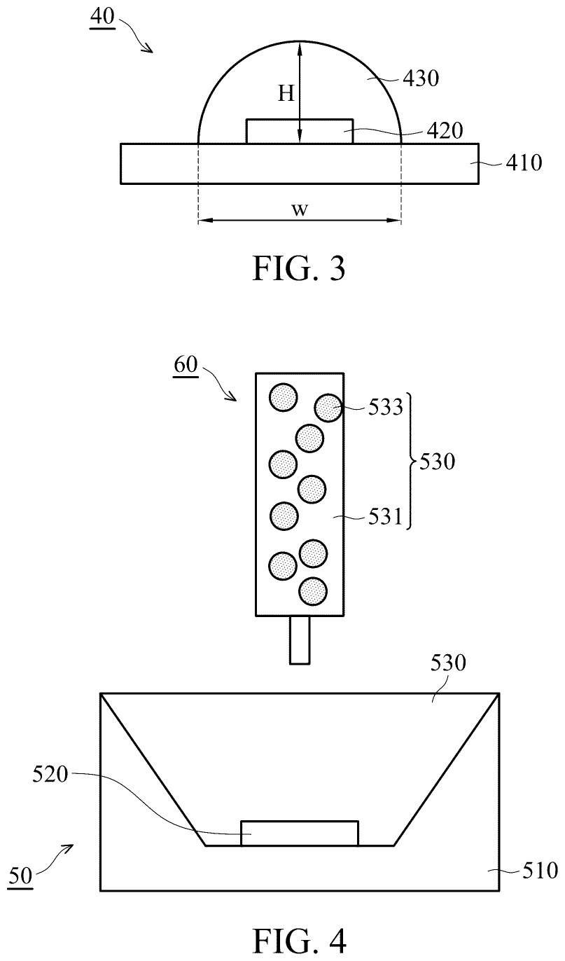

FIG. 3 is a schematic diagram of an optical device 40 including the encapsulation material in the present embodiment. The optical device 40 includes a package substrate 410, a light-emitting diode chip 420 fixed on the package substrate 410, and composite encapsulation material 430 covering the light-emitting diode chip 420. The packaging substrate 410 in the present embodiment is not limited particularly, and may be adjusted according to the requirements of the optical device 40. The substrate 410 may be made of, for example, a rigid printed circuit board, an aluminum substrate with high thermal conductivity, a ceramic substrate, a flexible printed circuit board, or metal composite materials. The light-emitting diode chip 420 is not limited particularly, and may be adjusted according to the requirements of the optical device 40. The material of the light-emitting diode chip 420 may be aluminum gallium arsenide (AlGaAs), gallium arsenide phosphide (GaAsP), gallium phosphide (GaP), aluminum gallium indium phosphide (AlGaInP) or the like that can emit red light; indium gallium nitride (InGaN), zinc selenide (ZnSe), indium gallium nitride/gallium nitride (InGaN/GaN) or the like that can emit blue light; indium gallium nitride/gallium nitride (InGaN/GaN), gallium phosphide (GaP), aluminum gallium phosphide (AlGaP) or the like that can emit green light, or a combination thereof. The composite encapsulation material 430 includes the above-mentioned polymer glue material (A) and the above-mentioned viscosity modifier (B), and additives can be added according to requirements, which will not be repeated hereafter. The light-emitting diode chip 420 can be bonded on the package substrate 410 by conventional method and packaged with composite encapsulation material 430. Since being under unstressed state, the molecular of the composite encapsulation material in the present embodiment is entangled to form a net structure, which limits the spreading state of the glue material. Therefore, the composite encapsulation material can maintain its shape after dispensing and other processes and form a lens shape with a height H and a width W on the substrate, as shown in FIG. 3. The height H is the distance between the bottom surface of the composite encapsulation material 430 and the apex of the composite encapsulation material 430, and the width W is the maximum width of the bottom surface of the composite encapsulation material 430. The encapsulation material 430 has an ideal aspect ratio (H/W), which can improve the light extraction efficiency of the optical device 40.

In contrast, the molecular structure of conventional encapsulation material does not change whether it is under stress and conventional encapsulation material has better adhesion property due to the good wetting effect of the glue material and the substrate. Therefore, the conventional encapsulation material has difficulty maintaining the shape after dispensing and other processes. For example, the glue material may spread so the conventional encapsulation material cannot form an ideal lens shape by itself, which affects the light extraction efficiency.

FIG. 4 is a schematic diagram of another optical device 50 including the encapsulation material in the present embodiment. The optical device 50 includes a packaging substrate 510, a light-emitting diode chip 520 fixed on the packaging substrate 510, and an encapsulation material 530 covering the light-emitting diode chip 520. The packaging substrate 510 may include plastic, ceramic, or a combination thereof. Specifically, the substrate 510 may be a plastic leaded chip carrier (PLCC), a ceramic leaded chip carrier, or the like. The materials of the LED chip 520 and the LED chip 420 may be the same. The encapsulation material 530 includes the above-mentioned polymer glue material (A) and the above-mentioned viscosity modifier (B), and additives may be added as required. It should be noted that the composite encapsulation material 530 further includes the above-mentioned phosphor powder as the color conversion encapsulation material. The light-emitting diode chip 520 can be bonded on the packaging substrate 510 and packaged with the composite encapsulation material 530. In some embodiments, the optical device 50 is packaged using a dispensing syringe 60. The dispensing syringe 60 is filled with the composite encapsulation material 530. In the encapsulation material 530, the phosphor powder 533 can be uniformly mixed with the polymer glue material 531 and other materials (not shown) of the composite encapsulation material 530. After the light-emitting diode chip 520 is packaged with the composite encapsulation material 530, the phosphor powder 533 can still be evenly distributed in the encapsulation material 530 of the optical device 50. In addition, the composite encapsulation material 530 filled in the dispensing syringe 60 does not delaminate after standing at room temperature for 4 hours.

In contrast, the conventional encapsulation material is filled in the same type of dispensing syringe. After standing at room temperature for 4 hours, the delamination can be observed obviously and the phosphor powder in the conventional encapsulation material sediments.

The present embodiment is described in more detail herein based on various examples, but the present embodiment is not limited thereto. The “parts” in the table refers to “parts by weight (wt %)”, and each example regards the polymer glue material as 100 parts by weight.

### Experimental Materials

TiO₂-A: surface substance-hydrophobic surface treatment agent,
SiO₂-A: no surface coating, nanomaterial, pure SiO₂ with the particle size of 7 nm,
SiO₂-B: surface coated with dimethyldichlorosilane,
SiO₂-C: surface coated with polydimethylsiloxane,
SiO₂-D: no surface coating, nanomaterial; pure SiO₂ with the particle size of 10 μm,

### Determination of Viscosity

The rheometer (MCR-102) manufactured by Anton Paar was used to measure the viscosity of the encapsulation material of different examples at 25° C. A Parallel-Plate with a diameter of 25 mm was used, the measurement gap was 250 μm, scan measuring is conducted at a shear rate of 0.001 s⁻¹-1000 s⁻¹, and the value of log(η₀)/log(η_{∞}) value was calculated from the obtained data.

### Experimental Group 1—Same Ratio Powder Experiment

TABLE 1

| | | Luminescent material | | | | | | | | | | | |
|---|---|---|---|---|---|---|---|---|---|---|---|---|---|
| | | green | Red | | | | | | | | | | |
| | | phosphor | phosphor | quantum | | | | | | | | | |
| | | powder | powder | dot | non-luminous material | | | | | | | | log |
| | Polymer | (30 μm) | (40 μm) | (50 nm) | Additive 1 | | | | Additive 2 | | | | (η₀)/ |
| Experiment | glue | added | added | added | | | Particle | added | | Particle | | added | log |
| description | material | amount | amount | amount | filler | coating | size | amount | filler | size | coating | amount | (η_{∞}) |
| Comparative | Silicone- | — | — | — | — | — | — | — | — | — | — | — | 1.00 |
| example | A | | | | | | | | | | | | |
| A0 | | | | | | | | | | | | | |
| Example | Silicone- | — | — | — | TiO₂-A | ◯ | 250 nm | 25 parts | — | — | — | — | 1.16 |
| A1 | A | | | | | | | | | | | | |
| Example | Silicone- | — | — | — | TiO₂-A | ◯ | 250 nm | 50 parts | — | — | — | — | 1.50 |
| A2 | A | | | | | | | | | | | | |
| Example | Silicone- | 25 parts | 25 parts | — | — | — | — | — | — | — | — | — | 1.05 |
| A3 | A | | | | | | | | | | | | |
| Example | Silicone- | 25 parts | 25 parts | — | — | — | — | — | SiO₂-A | 7 nm | X | 2 parts | 1.86 |
| A4 | A | | | | | | | | | | | | |
| Example | Silicone- | 50 parts | — | — | — | — | — | — | — | — | — | — | 1.01 |
| A5 | A | | | | | | | | | | | | |
| Example | Silicone- | — | 50 parts | — | — | — | — | — | — | — | — | — | 1.05 |
| A6 | A | | | | | | | | | | | | |
| Example | Silicone- | — | — | 50 parts | — | — | — | — | — | — | — | — | 2.16 |
| A7 | A | | | | | | | | | | | | |
| Example | Silicone- | — | — | — | — | — | — | — | SiO₂-D | 10 um | X | 50 parts | 1.01 |
| A8 | A | | | | | | | | | | | | |

### Comparative Example A0

Neither luminescent material nor non-luminescent nanomaterial was added to Comparative Example A0, and Comparative Example A0 was used as a comparison standard.

### Example A1

Non-luminescent nanomaterial was added in Example A1. According to the formula shown in table 1, 100 parts by weight (Wt %) of the Silicone-A and 25 parts by weight (Wt %) of the TiO₂-A were substantially mixed at room temperature by stirring in the same direction at for 10-15 minutes. Then the stirred encapsulation material was put into a vacuum apparatus for degassing, and the vacuum state at room temperature was maintained until there were no air bubbles in the encapsulation material.

### Examples A2 and A8

Non-luminescent nanomaterials were added in Examples A2 and A8. Examples A2 and A8 were prepared in the same way as Example A1 except that the types and proportions of the added non-luminescent nanomaterial were adjusted according to Table 1.

### Example A3

Luminescent materials were added in Example A3. According to the formula shown in Table 1, 100 parts by weight (wt %) of Silicone-A, 25 parts by weight of the green phosphor powder and 25 parts by weight of the red phosphor powder were mixed in Example 3. After 10-15 minutes of stirring in the same direction, which makes the materials be substantially mixed, the stirred encapsulation material was put into a vacuum apparatus for degassing, and the vacuum state at room temperature was maintained until there were no air bubbles in the encapsulation material.

### Example A4

Luminescent material and non-luminescent nanomaterial were added in Example A4. According to the formula shown in Table 1, 100 parts by weight of Silicone-A, 2 parts by weight of SiO₂-A were fully mixed by stirring in the same direction for 10-15 minutes. Then, 25 parts by weight of green phosphor powder and 25 parts by weight of red phosphor powder were added and fully mixed by 10-15 minutes of stirring in the same direction. The stirred encapsulation material was put into a vacuum apparatus for degassing, and the vacuum state at room temperature was maintained until there were no air bubbles in the encapsulation material.

### Examples A5-A7

Luminescent materials were added in Examples A5-A7, except that the ratio of the added luminescent materials were adjusted according to Table 1, Examples A5-A7 were prepared in the same manner as in Example A3.

Through the viscosity of different examples in Experimental group 1, the encapsulation material with substantially same ratio of powder were compared.

First, Examples A1-A2 and A8 and comparative example A0 were compared. There were TiO₂-A with particle size 250 nm added in both Examples A1-A2. In comparison to comparative example A0, the value of (log(η₀)/log(η_{∞})) of the composite encapsulation material of A1-A2 increased significantly, and the value of (log(η₀)/log(η_{∞})) rose when the the amount of TiO₂-A added was also increased. In contrast, though there was non-luminescent nanomaterial of the same 50 parts by weight added in Example A8 as in Example A2, the particle size of SiO₂-D was 10 μm, the surface of SiO₂-D was untreated, and thus it was difficult to increase the value of (log(η₀)/log(η_{∞})) of the encapsulation material.

Next, Examples A3-A7 and comparative Example A0 were compared. There were 50 parts by weight of the luminescent materials added in all Example A3-A7. 25 parts by weight of green phosphor powder and 25 parts by weight of red phosphor powder were added in Example A3, but the particle size of the two were both over 500 nm, which has little effect on the value of (log(η₀)/log(η_{∞})) of the encapsulation material. In contrast, in Example A4, in addition to the material in Example A3, 2 parts by weight of the SiO₂-A was added, which has the particle size of 7 nm and can increase the value of (log(η₀)/log(η_{∞})) of the encapsulation material significantly. Similarly, there were not many changes in the values of (log(η₀)/log(η_{∞})) of Example 5 with 50 parts by weight of the green phosphor powder added and of Example 6 with 50 parts by weight of the red phosphor powder added, in comparison to the comparative Example A0. On the other hand, 50 parts by weight of the quantum dot with the particle size of 50 nm was added to Example 7, and the quantum dot significantly affected the value of (log(η₀)/log(η_{∞})) of the encapsulation material.

In summary, when the size of the powder material added to the encapsulation material is greater than 500 nm, the (log(η₀)/log(η_{∞})) value of the encapsulation material cannot be greater than 1.1, so the phosphor powder used in conventional light-emitting diodes cannot improve the viscosity of the encapsulation material.

### Experimental Group 2—Anti Sedimentation Experiment

TABLE 2

| | | Luminescent material | | | | | | | | | | | | |
|---|---|---|---|---|---|---|---|---|---|---|---|---|---|---|
| | | green | Red | quan- | | | | | | | | | | |
| | | phosphor | phosphor | tum | | | | | | | | | | Anti- |
| | | powder | powder | dot | non-luminous material | | | | | | | | log | sedi- |
| | Polymer | (30 μm) | (40 μm) | (50 nm) | Additive 1 | | | | Additive 2 | | | | (η₀)/ | men- |
| Experiment | glue | added | added | added | | | Particle | added | | Particle | | added | log | tation |
| description | material | amount | amount | amount | filler | coating | size | amount | filler | size | coating | amount | (η_{∞}) | effect |
| comparative | Silicone- | — | — | — | — | — | — | — | — | — | — | — | 1.00 | X |
| example | B | | | | | | | | | | | | | |
| B0 | | | | | | | | | | | | | | |
| Example | Silicone- | — | — | — | — | — | — | — | SiO₂-A | 7 nm | X | 1 parts | 1.55 | ◯ |
| B1 | B | | | | | | | | | | | | | |
| Example | Silicone- | — | — | — | — | — | — | — | SiO₂-B | 7 nm | ◯ | 1 parts | 1.37 | ◯ |
| B2 | B | | | | | | | | | | | | | |
| Example | Silicone- | — | — | — | — | — | — | — | SiO₂-C | 14 nm | ◯ | 1 parts | 1.21 | Δ |
| B3 | B | | | | | | | | | | | | | |
| Example | Silicone- | — | — | — | — | — | — | — | SiO₂-C | 14 nm | ◯ | 0.6 parts | 1.10 | Δ |
| B4 | B | | | | | | | | | | | | | |

In Table 2, “x” refers to no anti-sedimentation effect; “Δ” refers to slight anti-settling effect; “O” refers to good anti-settling effect.

### Comparative Example B0

Neither luminescent material nor non-luminescent nanomaterial was added in comparative example B0, which was used as the standard in comparison.

### Example B1

The non-luminescent nanomaterial was added in Example B1. According to the formula shown in Table 2, 100 parts by weight of Silicone-B and 1 part by weight of SiO₂-A were fully mixed by stirring in the same direction for 10-15 minutes. Then the mixed composite encapsulation material was put into a vacuum apparatus for degassing, and the vacuum state at room temperature was maintained until there were no air bubbles in the encapsulation material.

### Examples B2-B4

Except the type and ratio of the added SiO₂ were changed, Example B2-B4 were prepared in the same manner as in the Example B1.

Then, a part of the prepared examples B0-B4 were tested for viscosity, and the remainder each were mixed with 25 parts by weight of green phosphor powder (30 μm). After stirring in the same direction for 10-15 minutes, the materials are substantially mixed. The stirred encapsulation material were put into a vacuum apparatus for degassing, and the vacuum state at room temperature was maintained until there were no air bubbles in the encapsulation material. The degassed materials were injected into the dispensing syringes and leave stand at room temperature for 4 hours to observe whether the phosphor powder sediment.

The anti-sedimentation effect was compared in experimental group 2 by adding different SiO₂ material. According to Table 2, it can be seen that in comparison with the comparative example B0 without SiO₂, the (log(η₀)/log(η_{∞})) values of the examples B1-B4 with SiO₂ were significantly improved.

The Examples B1-B3 and the comparative example B0 were compared. With the same amount of SiO₂ added in example B1-B3, the SiO₂-A added in Example B1 had no surface treatment, the SiO₂-B added in Example B2 were coated with dimethyl dichlorosilane and the SiO₂-C added in Example B3 were coated with polydimethylsiloxane. The different functional group on the SiO₂ resulted in different values of (log(η₀)/log(η_{∞})) of Examples B1-B3. In addition, since the bonding force of hydrogen bond of the SiO₂-A without coating in example B1 was stronger, it was easier for Example B1 to form a tangled net structure, and the value of (log(η₀)/log(η_{∞})) of Example B1 is greater than that of Example B2.

Next, Examples B3 and B4 were compared. SiO₂-C was added in both Examples B3-B4. The polydimethylsiloxane coating of SiO₂-C can form non-covalent interaction with polymer glue material, hence the higher the ratio of the added SiO₂-C had, the stronger the bonding forcing between the encapsulation material was, which made the value of (log(η₀)/log(η_{∞})) of the encapsulation material greater and the effect of the anti-sedimentation better.

In summary, with the same ratio of different types of SiO₂, the value of (log(η₀)/log(η_{∞})) of the encapsulation material varied due to the different surface condition of SiO₂. This is because different non-covalent bonds were formed between SiO₂ particles and between SiO₂ particles and polymer glue material, resulting in different molecular structure entanglement.

### Experimental Group 3—Transparent Lens Experiment

TABLE 3

| | | Luminescent material | | | | | | | | | | | |
|---|---|---|---|---|---|---|---|---|---|---|---|---|---|
| | | green | Red | | | | | | | | | | |
| | | phosphor | phosphor | quantum | | | | | | | | | |
| | | powder | powder | dot | non-luminous material | | | | | | | | log |
| | Polymer | (30 μm) | (40 μm) | (50 nm) | Additive 1 | | | | Additive 2 | | | | (η₀)/ |
| Experiment | glue | added | added | added | | | Particle | added | | Particle | | added | log |
| description | material | amount | amount | amount | filler | coating | size | amount | filler | size | coating | amount | (η_{∞}) |
| Comparative | Silicone- | — | — | — | — | — | — | — | — | — | — | — | 1.00 |
| example | C | | | | | | | | | | | | |
| C0 | | | | | | | | | | | | | |
| Example | Silicone- | — | — | — | — | — | — | — | SiO₂-A | 7 nm | X | 1 parts | 1.48 |
| C1 | C | | | | | | | | | | | | |
| Example | Silicone- | — | — | — | — | — | — | — | SiO₂-A | 7 nm | X | 4 parts | 1.99 |
| C2 | C | | | | | | | | | | | | |
| Example | Silicone- | — | — | — | — | — | — | — | SiO₂-A | 7 nm | X | 6 parts | 2.03 |
| C3 | C | | | | | | | | | | | | |
| Example | Silicone- | — | — | — | — | — | — | — | SiO₂-A | 7 nm | X | 9 parts | 2.26 |
| C4 | C | | | | | | | | | | | | |
| Comparative | Silicone- | — | — | — | — | — | — | — | — | | | | 1.00 |
| example | D | | | | | | | | | | | | |
| D0 | | | | | | | | | | | | | |
| Example | Silicone- | — | — | — | — | — | — | — | SiO₂-A | 7 nm | X | 3 parts | 1.97 |
| D1 | D | | | | | | | | | | | | |
| Example | Silicone- | — | — | — | — | — | — | — | SiO₂-A | 7 nm | X | 4 parts | 2.27 |
| D2 | D | | | | | | | | | | | | |
| Example | Silicone- | — | — | — | — | — | — | — | SiO₂-A | 7 nm | X | 9 parts | 2.50 |
| D3 | D | | | | | | | | | | | | |

### Comparative Example C0 and D0

Neither luminescent material nor non-luminescent nanomaterial was added in Comparative example C0 and D0, and the two were used as standard in comparison.

### Example C1

The non-luminescent nanomaterial was added in Example C1. According to the formula shown in Table 3, 100 parts by weigh of Silicone-C and 1 part by weight of SiO₂-A were substantially mixed after stirring in the same direction for 10-15 minutes. Then the mixed composite encapsulation material was put into a vacuum apparatus for degassing, and the vacuum state at room temperature was maintained until there were no air bubbles in the encapsulation material.

### Examples C2-C4

Except for the change of the amount of SiO₂-A added according to Table 3, Examples C2-C4 were prepared in the same manner as in Example C1.

### Example D1-D3

Except for the change of the polymer glue material to Silicone-D according to Table 3, Examples D1-D3 were prepared in the same manner as in Example C1.

A part of the prepared encapsulation material was tested for viscosity, and other part of that is used for dispensing. A dispenser was used to control the dispensing volume to 6 μL, and dispensed the encapsulation material on the die-bonded substrate at room temperature. After dispensing, the encapsulation material forms the shape of the lens on the substrate, and the aspect ratio of the formed lens is measured.

Examples C1-C3 and D1-D3 in the experimental group 3 can form transparent lens on the substrate, and when the value of log(η₀)/log(η_{∞}) of the encapsulation material was about 1.5, the aspect ratio of the formed lens was about 0.10-0.20. When the value of log(η₀)/log(η_{∞}) of the encapsulation material was about 2.0, the aspect ratio of the formed lens was about 0.4-0.6; when the value of log(η₀)/log(η_{∞})) of the encapsulation material was greater than 2.0, the aspect ratio of the formed lens was about 0.7-1.0.

To sum up, since being under unstressed state, the molecular structure of the encapsulation material in the present embodiment entangled to form a net structure, which limits the spreading state of the polymer glue material, so it can form a lens shape on the substrate (as shown in FIG. 3). The larger the value of log(η₀)/log(η_{∞}) of the encapsulation material was, the denser the net structure between the encapsulation material molecules became, and the greater the spreading state was restricted, and thus the larger the aspect ration the resulting lens had. By controlling the value of log(η₀)/log(η_{∞}), the encapsulation material can be formed into lens shapes with different aspect ratios on the substrate.

### Experimental Group 4—White Lens Experiment

TABLE 4

| | | Luminescent material | | | | | | | | | | | |
|---|---|---|---|---|---|---|---|---|---|---|---|---|---|
| | | green | Red | | | | | | | | | | |
| | | phosphor | phosphor | quantum | | | | | | | | | |
| | | powder | powder | dot | non-luminous material | | | | | | | | log |
| | Polymer | (30 μm) | (40 μm) | (50 nm) | Additive 1 | | | | Additive 2 | | | | (η₀)/ |
| Experiment | glue | added | added | added | | | Particle | added | | Particle | | added | log |
| description | material | amount | amount | amount | filler | coating | size | amount | filler | size | coating | amount | (η_{∞}) |
| comparative | Silicone- | — | — | — | — | — | — | — | — | — | — | — | 1.00 |
| example | C | | | | | | | | | | | | |
| C0 | | | | | | | | | | | | | |
| Example | Silicone- | — | — | — | TiO₂-A | ◯ | 250 nm | 40 parts | SiO₂-A | 7 nm | X | 1 parts | 1.96 |
| C5 | C | | | | | | | | | | | | |
| Example | Silicone- | — | — | — | TiO₂-A | ◯ | 250 nm | 40 parts | SiO₂-A | 7 nm | X | 3 parts | 1.99 |
| C6 | C | | | | | | | | | | | | |

### Example C5

The non-luminescent nanomaterial was added in Example C5. According to the formula shown in Table 4, 100 parts by weigh of Silicone-C and 1 part by weight of SiO₂-A were substantially mixed after stifling in the same direction for 10-15 minutes. Then 40 parts by weight of the TiO₂-A was added and substantially mixed by stifling in the same direction for 10-15 minutes. Then the mixed composite encapsulation material was put into a vacuum apparatus for degassing, and the vacuum state at room temperature was maintained until there were no air bubbles in the encapsulation material.

### Example 6

Except for the change of the amount of SiO₂-A added according to Table 4, Example C5 was prepared in the same manner as in Example C5.

Part of the prepared encapsulation material was tested for viscosity, and other part was used for dispensing. A dispenser was used to control the dispensing volume to 6 μL, and dispensed the encapsulation material on the die-bonded substrate at room temperature. After dispensing, the encapsulation material forms the shape of the lens on the substrate, and the aspect ratio of the formed lens is measured.

Due to the addition of TiO₂, Examples C5 and C6 in the experimental group 4 can form a white lens on the substrate (as shown in FIG. 3), and the value of log(η₀)/log(η_{∞}) of the encapsulation material were all about 2.0, and the aspect ratio of the formed lens were about 0.4-0.6.

### Experimental Group 5—High Powder Ratio Experiment

TABLE 5

| | | Luminescent material | | | | | | | | | | | |
|---|---|---|---|---|---|---|---|---|---|---|---|---|---|
| | | green | Red | | | | | | | | | | |
| | | phosphor | phosphor | quantum | | | | | | | | | |
| | | powder | powder | dot | non-luminous material | | | | | | | | log |
| | Polymer | (30 μm) | (40 μm) | (50 nm) | Additive 1 | | | | Additive 2 | | | | (η₀)/ |
| Experiment | glue | added | added | added | | | Particle | added | | Particle | | added | log |
| description | material | amount | amount | amount | filler | coating | size | amount | filler | size | coating | amount | (η_{∞}) |
| comparative | Silicone- | — | — | — | — | — | — | — | — | — | — | — | 1.00 |
| example | D | | | | | | | | | | | | |
| D0 | | | | | | | | | | | | | |
| Example | Silicone- | — | — | — | TiO₂-A | ◯ | 250 nm | 100 parts | — | — | — | — | 1.94 |
| D4 | D | | | | | | | | | | | | |
| Example | Silicone- | — | — | — | TiO₂-A | ◯ | 250 nm | 120 parts | — | — | — | — | 1.86 |
| D5 | D | | | | | | | | | | | | |

### Example D4

According to the formula shown in Table 5, 100 parts by weigh of TiO₂-A was added in 100 parts by weight of Silicone-D in several portions and stirred. Before each time of adding TiO₂-A, the materials were substantially mixed. After TiO₂-A were substantially mixed after stifling in the same direction for 10-15 minutes, the mixed composite encapsulation material was put into a vacuum apparatus for degassing, and the vacuum state at room temperature was maintained until there were no air bubbles in the encapsulation material.

### Example D5

Except for the change of the amount of TiO₂-A added according to Table 5, Example D5 was prepared in the same manner as in Example D4.

In the experimental group 5, the examples with high proportion of TiO 2 added were compared. 100 parts by weight of TiO₂-A was added in Example D4, and 120 parts by weight of TiO₂-A was added in Example D5. The value of log(η₀)/log(η_{∞}) of Examples D4-D5 both fell above 1.5. The log(η₀)/log(η_{∞}) of Example D5 decreased in comparison with that of Example D4, which was due to the normal fluctuation of value in the viscosity measurement.

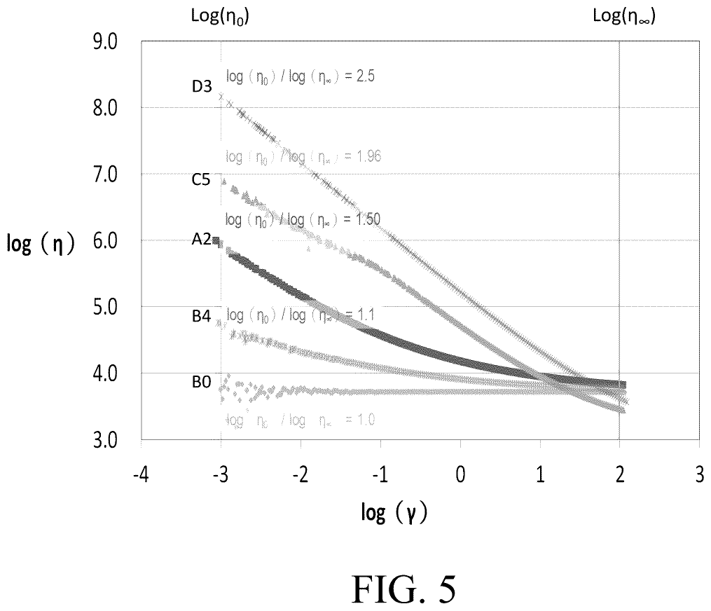

Then referring to FIG. 5, which is the schematic diagram of the relationship of the logarithm of viscosity (log(η)) and logarithm of shear rate (log(γ)) at room temperature (25° C.±5° C.) of different examples and comparative examples. In FIG. 5, “η₀” refers to the viscosity of the encapsulation material at room temperature when the shear rate (γ) is 1×10⁻³ s⁻¹. “η₀” refers to the viscosity of the encapsulation material at room temperature when the shear rate (γ) is 1×10² s⁻¹. Line D3 is the log(η)-log(γ) curve of Example D3, line C5 is the log(η)-log(γ) curve of Example C5, line A2 is the log(η)-log(γ) curve of Example A2, line B4 is the log(η)-log(γ) curve of Example B4, and line B0 is the log(η)-log(γ) curve of comparative example B0. It can be seen that the viscosity of the composite encapsulation material in the present embodiment decreases as the shear rate increases, and the value of (log(η₀)/log(η_{∞})) falls within the range of 1.1-2.5. In contrast, the viscosity of Comparative Example B0 without the specific viscosity modifier is almost constant under different shear rates, and the value of (log(η₀)/log(η_{∞})) of B0 is about 1. In addition, when the shear rate (γ) is 1×10² s⁻¹, the viscosity of the encapsulation material is not much different from that of Comparative Example B0.

From the above examples and comparative examples, it can be seen that the composite encapsulation material in the present embodiment has an anti-sedimentation effect and can form a lens shape by itself, while maintaining its processability.

In the present embodiment, the encapsulation material has a tangled net structures when a viscosity modifier is added, which has a functional group that can form a non-covalent interaction with the polymer glue material in the encapsulation material. encapsulation material Therefore, under unstressed state, the composite encapsulation material can maintain its shape and avoid the sedimentation of phosphor powder therein.

In addition, the viscosity of the encapsulation material in the present embodiment decreases when being stressed, so that the composite encapsulation material can be used in packaging processes such as dispensing.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A composite encapsulation material, comprising:
(A) a polymer glue material; and
(B) a viscosity modifier, wherein the viscosity modifier (B) has a functional group capable of forming a non-covalent interaction with the polymer glue material (A);
wherein, at room temperature, a ratio (log(η₀)/log(η_{∞})) of a logarithm of a viscosity ((log(η₀)) of the composite encapsulation material at a shear rate of 1×10⁻³ s⁻¹ to a logarithm of a viscosity (log(η_{∞})) of the composite encapsulation material at a shear rate of 1×10² s⁻¹ is 1.1-2.5.

2. The composite encapsulation material as claimed in claim 1, wherein the composite encapsulation material has a tangled net structure.

3. The composite encapsulation material as claimed in claim 1, wherein the non-covalent interaction comprise a van der Waals force, a hydrogen bond, an ionic bond, a hydrophobic force, or a combination thereof.

4. The composite encapsulation material as claimed in claim 1, wherein the polymer glue material (A) comprises a siloxane bond, a carbon-hydrogen bond, or a combination thereof.

5. The composite encapsulation material as claimed in claim 1, wherein the polymer glue material (A) comprises a silicone resin, an epoxy resin, a fluororesin, or a combination thereof.

6. The composite encapsulation material as claimed in claim 1, wherein the functional group of the viscosity modifier (B) comprises —OH, ═NH, —NH₂, halogen, hydrocarbon chain, or a combination thereof.

7. The composite encapsulation material as claimed in claim 1, wherein the viscosity modifier (B) comprises a polymer material, a nanomaterial, or a combination thereof.

8. The composite encapsulation material as claimed in claim 7, wherein the polymer material comprises a polyamide wax, an organic bentonite clay, a hydrogenated castor oil, or a combination thereof.

9. The composite encapsulation material as claimed in claim 7, wherein a particle size of the nanomaterial is 1 nm to 500 nm.

10. The composite encapsulation material as claimed in claim 7, wherein based on 100 parts by weight of the polymer glue material (A), the nanomaterial is 0.1-130 parts by weight (wt %).

11. The composite encapsulation material as claimed in claim 7, wherein the nanomaterial comprises a luminescent material, a non-luminescent material, or a combination thereof.

12. The composite encapsulation material as claimed in claim 11, wherein the luminescent material comprises quantum dots.

13. The composite encapsulation material as claimed in claim 11, wherein the non-luminescent material comprises TiO₂, SiO₂, Al₂O₃, or a combination thereof.

14. The composite encapsulation material as claimed in claim 7, wherein based on 100 parts by weight of the polymer glue material (A), the polymer material is 1-100 parts by weight (wt %).

15. The composite encapsulation material as claimed in claim 1, further comprising phosphor powder.

16. An optical device, comprising the composite encapsulation material as claimed in claim 1.

17. The optical device as claimed in claim 16, further comprising a light-emitting unit, wherein the composite encapsulation material covers the light-emitting unit of the optical devices.

18. The optical device as claimed in claim 16, further comprising an optical unit, wherein the optical unit is made of the composite encapsulation material.

19. The optical device as claimed in claim 18, wherein the optical unit is a lens.
